(19) United States
(12) Patent Application Publication
(10) Pub. No.: US 2021/0208518 A1
(43) Pub. Date: Jul. 8, 2021

(54) APPARATUS TO MOVE AN OBJECT IN AND/OR OUT OF A HOUSING

(71) Applicant: ASML NETHERLANDS B.V., Veldhoven (NL)

(72) Inventors: Marc Cornelis Pieter VAN BAKEL, Veldhoven (NL); Gabrielle VAN OYEN, AH Veldhoven (NL)

(21) Appl. No.: 16/338,713

(22) PCT Filed: Oct. 9, 2017
(86) PCT No.: PCT/EP2017/075679

§ 371 Date: Apr. 2, 2019

(30) Foreign Application Priority Data
Oct. 24, 2016 (EP) 16195201.5

(51) Int. Cl. G03F 7/20; H01L 21/677

(52) U.S. Cl. CPC G03F 7/70975; H01L 21/67748; G03F 7/70741

(57) ABSTRACT

An apparatus for moving an object in and/or out of a housing, for example for moving a support structure for a mask out of a housing of a lithographic apparatus. The apparatus includes a first guiding mechanism moveable in a first direction and which is rotatably connectable to a first part of the object, and a second guiding mechanism moveable in a second direction and which is rotatably connectable to a second part of the object, wherein the second part is different from the first part and the second direction is different from the first direction. The rotatable connections define a rotation around an axis which extends in a third direction which is substantially perpendicular to the first direction and the second direction.

### CROSS-REFERENCE TO RELATED APPLICATIONS

This application claims priority of EP application no. 16195201.5, which was filed on 24 Oct. 2016 and which is incorporated herein its entirety be reference.

### FIELD

The present invention relates to an apparatus and method for moving an object in and/or out of a housing. The invention relates more particularly to an apparatus for exchanging a support structure for a mask in and/or out of a housing of a lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

In some cases a part of the lithographic apparatus needs to be upgraded. In that case the old part is removed from the lithographic apparatus and is replaced by an upgraded part. For example a support structure for the patterning device, also named reticle stage, may need to be swapped with a newer version.

However, not always the required space is available around a semiconductor manufacturing apparatus, such as a lithographic apparatus in a factory environment to take a part, or object, out of the semiconductor manufacturing apparatus in a conventional way, especially in case of relatively large objects. In general, therefore, there is a need for a method and apparatus to remove an object from a housing, for example the housing of a semiconductor manufacturing or lithographic apparatus, and to put an object into the housing in an environment where the available space is not sufficiently large to handle and/or transport the object.

### SUMMARY OF THE INVENTION

According to an aspect, there is provided an apparatus for moving an object in and/or out of a housing, the apparatus comprising a first guiding mechanism moveable in a first direction and which is rotatably connectable to a first part of the object, and a second guiding mechanism moveable in a second direction and which is rotatably connectable to a second part of the object, wherein the second part is different from the first part and the second direction is different from the first direction. The rotatable connections define a rotation around an axis which extends in a third direction which is substantially perpendicular to the first direction and the second direction.

In this way the object, e.g. a reticle stage, will be moved out of the housing, e.g. a lithographic apparatus, from a horizontal orientation, i.e. generally extending along a second direction, for example X-direction, to a vertical orientation, i.e. generally extending along a first direction, for example Z-direction. This requires less space/volume and less time for taking out the object from the housing than the conventional solutions. The rotatable connections enable the object to be rotated around the axis extending in a third direction and in cooperation with the first and second guiding mechanism the object is moved into or out of the housing while the changing the orientation of the object from a first (e.g. horizontal) to a second (e.g. vertical) orientation. In other words, the apparatus according to the invention is arranged to move the object into or out of the housing by a combination of a translation and a rotation of the object.

In an embodiment the first guiding mechanism comprises a first guide which is rotatably connectable to the first part of the object, and wherein the second guiding mechanism comprises a second guide which is rotatably connectable to the second part of the object,

The first and second guides are arranged to be guided by and along the first and second guiding mechanisms, respectively. Furthermore, the first and second guides are arranged to be rotatably connected, or coupled, to the object at two different parts of the object. In this embodiment the guides are arranged to move the object out or into the housing with a combined translation and rotation of the object.

In an embodiment the apparatus further comprises a lifting mechanism wherein the second guiding mechanism is fixated to the lifting mechanism for providing a movement of the second guiding mechanism in the first direction.

In this way the second can be put into any position along the first direction for moving in and/or out the object from the housing.

In an embodiment the lifting mechanism is fixated to the housing, which creates stability.

In an embodiment the apparatus further comprises a mechanical interface fixated to the object and wherein the first guiding mechanism and the second guiding mechanism are rotatably connectable to the object via the mechanical interface.

This provides for flexibility in taking out any object from a housing, wherein the object does not need to have rotatable connections, because these are implemented on the mechanical interface.

In an embodiment the mechanical interface comprises a first arm and a second arm extending substantially perpendicular to the first arm, wherein the first arm is rotatably connectable to the first guiding mechanism and the second arm is rotatably connectable to the second guiding mechanism.

The second arm extending perpendicular to the first arm provides for flexibility in the amount of space that needs to be available.

In an embodiment the first guiding mechanism is pivotable around an axis extending in the first direction.

In an embodiment the rotatable connections between the first and second guiding mechanisms and the object comprise a ball joint.

In an embodiment the rotatable connection between the first guiding mechanism and the object comprises a slotted socket extending in the first direction and a ball stud.

The slotted socket gives some freedom in moving of this connection along the first direction.

In an embodiment, the apparatus comprises two first guiding mechanisms, wherein one of the first guiding mechanisms is rotatably connectable to a first part of a first side of the object and the other one of the first guiding mechanisms is rotatably connectable to a first part of a second side of the object which is opposite to the first side, and two second guiding mechanisms, wherein one of the second guiding mechanisms is rotatably connectable to a second part of the first side of the object and the other one of the second guiding mechanisms is rotatably connectable to a second part of the second side of the object.

This enables the apparatus to move relatively large objects into and/or out of the housing.

In an embodiment the first guiding mechanism comprises a first guide which is rotatably connectable to the first part of the object, and the second guiding mechanism comprises a second guide which is rotatably connectable to the second part of the object,

The first and second guides are arranged to be guided by the first and second guiding mechanisms, respectively. Furthermore, the first and second guides are arranged to be rotatably connected, or coupled, to the object at two different parts of the object. When using the apparatus according to this embodiment, the guides will move the object out or into the housing with a combined translation and rotation of the object. The guides are, for example, sliders.

In embodiment the first guiding mechanism comprises a motor for driving the first guide in the first direction and for providing a movement of the second guide in the second direction.

In this embodiment only one motor is required to move both the first and the second guides because the second guide is (passively) following the first guide because both are connected to each other via the object.

In an embodiment the first guiding mechanism comprises a guiding trench comprising a first linear part connected to a second linear part and the first guide comprises a protrusion which engages in the guiding trench and is pivotably connectable to the first guiding mechanism, wherein the first and second linear part have an angle larger than 90 degrees and smaller than 180 degrees with respect to each other.

In this way the object can be moved in and/or out somewhat further in and/or out from the housing in the second direction.

In an embodiment the object comprises a support structure for a mask and the housing comprises the housing of a lithographic apparatus. In another embodiment the housing comprises the housing of a semiconductor manufacturing apparatus.

According to another aspect of the invention a method is provided for moving an object in and/or out of a housing, the method comprising the steps of rotatably connecting a first guide to a first part of the object; rotatably connecting a second guide to a second part of the object, which is different from the first part of the object; and moving the first guide in a first direction thereby moving the second guide in a second direction, which is different from the first direction, and rotating the object around an axis extending in a third direction which is substantially perpendicular to the first direction and the second direction.

Advantages of the apparatus of the invention apply similarly to the method according to the invention.

In an embodiment the method further comprises a step of moving the second guide in the first direction before moving the first guide in the first direction.

In an embodiment the method further comprising the steps of pivoting the first guide around an axis extending in the first direction to an open position; positioning a transport car in a location close the housing where the object is located; and pivoting the first guide around the axis extending in the first direction to an operating position. These additional steps are performed before rotatably connecting the first guide to the first part of the object.

### BRIEF DESCRIPTION OF THE DRAWINGS

Embodiments will now be described, by way of example only, with reference to the accompanying schematic drawings in which corresponding reference symbols indicate corresponding parts, and in which:

FIG. 1 depicts a lithographic apparatus;

FIG. 2 depicts an object that has to be removed from a housing;

FIGS. 3A-C depicts a method of moving an object from a housing according to an embodiment of the invention;

FIGS. 4-7 depict an apparatus according to embodiments of the invention for moving an object into and/or out of a housing according to an embodiment;

FIGS. 8A-B depicts an embodiment of a first guiding mechanism; and

FIG. 9 depicts an embodiment of a first guide.

### DETAILED DESCRIPTION

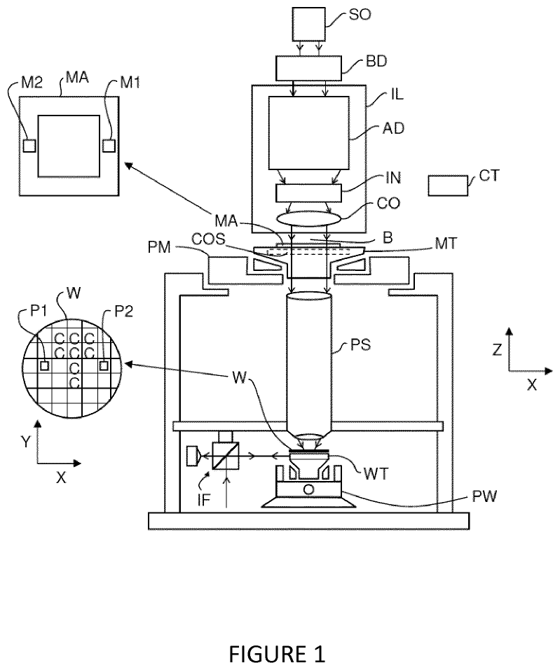

FIG. 1 schematically depicts a lithographic apparatus. The lithographic apparatus comprises an illumination system IL, a support structure MT, a substrate table WT and a projection system PS. The illumination system IL is configured to condition a radiation beam B. The support structure MT is constructed to support a patterning device MA and is connected to a first positioning system PM configured to accurately position the patterning device MA in accordance with certain parameters. The substrate table WT is constructed to hold a substrate W, e.g. a resist coated wafer, and is connected to a second positioning system PW configured to accurately position the substrate W in accordance with certain parameters. The projection system PS is configured to project a pattern imparted to the radiation beam B by patterning device MA onto a target portion C (e.g. comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The illumination system IL receives the radiation beam B from a radiation source SO. The radiation source SO and the lithographic apparatus may be separate entities, for example when the radiation source SO is an excimer laser. In such cases, the radiation source SO is not considered to form part of the lithographic apparatus and the radiation beam B is passed from the radiation source SO to the illumination system IL with the aid of a beam delivery system BD comprising, for example, suitable directing mirrors and/or a beam expander. In other cases the radiation source SO may be an integral part of the lithographic apparatus, for example when the radiation source SO is a mercury lamp. The radiation source SO and the illumination system IL, together with the beam delivery system BD if required, may be referred to as a radiation system.

The illumination system IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as an integrator IN and a condenser CO. The illumination system IL may be used to condition the radiation beam B, to have a desired uniformity and intensity distribution in its cross section.

The term “radiation beam” used herein encompasses all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The support structure MT holds the patterning device MA in a manner that depends on the orientation of the patterning device MA, the design of the lithographic apparatus, and other conditions, such as for example whether or not the patterning device MA is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” used herein should be broadly interpreted as referring to any device that can be used to impart a radiation beam with a pattern in its cross-section such as to create a pattern in a target portion C of the substrate W. It should be noted that the pattern imparted to the radiation beam B may not exactly correspond to the desired pattern in the target portion C of the substrate W, for example if the pattern includes phase-shifting features or so called assist features. Generally, the pattern imparted to the radiation beam B will correspond to a particular functional layer in a device being created in the target portion C, such as an integrated circuit.

The patterning device MA may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum.

As here depicted, the lithographic apparatus is of a transmissive type (e.g. employing a transmissive mask). Alternatively, the lithographic apparatus may be of a reflective type (e.g. employing a programmable mirror array of a type as referred to above, or employing a reflective mask).

The lithographic apparatus may be of a type having two (dual stage) or more substrate tables (and/or two or more patterning device support tables). In such “multiple stage” machines the additional tables may be used in parallel, or preparatory steps may be carried out on one or more tables while one or more other tables are being used for exposure. An additional table may be arranged to hold at least one sensor, instead of holding a substrate W. The at least one sensor may be a sensor to measure a property of the projection system PS, a sensor to detect a position of a marker on the patterning device MA relative to the sensor or may be any other type of sensor. The additional table may comprise a cleaning device, for example for cleaning part of the projection system PS or any other part of the lithographic apparatus.

The lithographic apparatus may also be of a type wherein at least a portion of the substrate W may be covered by a liquid having a relatively high refractive index, e.g. water, so as to fill a space between the projection system PS and the substrate W. An immersion liquid may also be applied to other spaces in the lithographic apparatus, for example, between the patterning device MA and the projection system PS. Immersion techniques are well known in the art for increasing the numerical aperture of projection systems. The term “immersion” as used herein does not mean that a structure, such as a substrate W, must be submerged in liquid, but rather only means that liquid is located between the projection system PS and the substrate W during exposure.

The radiation beam B is incident on the patterning device MA, which is held on the support structure MT, and is patterned by the patterning device MA. Having traversed the support structure MT, the radiation beam B passes through the projection system PS, which focuses the beam onto a target portion C of the substrate W. With the aid of the second positioning system PW and position sensor IF (e.g. an interferometric device, linear encoder or capacitive sensor), the substrate table WT can be moved accurately, e.g. so as to position different target portions C in the path of the radiation beam B. Similarly, the first positioning system PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module and a short-stroke module, which form part of the first positioning system PM. The long-stroke module provides movement of the support structure MT over a large range with limited accuracy (coarse positioning), whereas the short-stroke module provides movement of the support structure MT relative to the long-stroke module over a small range with high accuracy (fine positioning). Similarly, movement of the substrate table WT may be realized using a long-stroke module and a short-stroke module, which form part of the second positioning system PW. In the case of a stepper (as opposed to a scanner) the support structure MT may be connected to a short-stroke actuator only, or may be fixed.

Patterning device MA and substrate W may be aligned using patterning device alignment marks M1, M2 and substrate alignment marks P1, P2. Although the substrate alignment marks P1, P2 as illustrated occupy dedicated target portions, they may be located in spaces between target portions C. Substrate alignment marks P1, P2 are known as scribe-lane alignment marks, when they are located in spaces between the target portions C. Similarly, in situations in which more than one die is provided on the patterning device MA, the patterning device alignment marks M1, M2 may be located between the dies.

The depicted apparatus could be used in at least one of the following modes:

In a first mode, the step mode, the support structure MT and the substrate table WT are kept essentially stationary, while an entire pattern imparted to the radiation beam B is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.
In a second mode, the scan mode, the support structure MT and the substrate table WT are scanned synchronously while a pattern imparted to the radiation beam B is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion C in a single dynamic exposure, whereas the length of the scanning motion determines the height (in the scanning direction) of the target portion C.
In a third mode, the support structure MT is kept essentially stationary holding a programmable patterning device MA, and the substrate table WT is moved or scanned while a pattern imparted to the radiation beam B is projected onto a target portion C. In this mode, generally a pulsed radiation source is employed and the programmable patterning device MA is updated as required after each movement of the substrate table WT or in between successive radiation pulses during a scan. This mode of operation can be readily applied to maskless lithography that utilizes programmable patterning device, such as a programmable mirror array of a type as referred to above.

The lithographic apparatus further includes a control unit which controls the actuators and sensors described. The control unit also includes signal processing and data processing capacity to implement desired calculations relevant to the operation of the lithographic apparatus. In practice, the control unit will be realized as a system of many sub-units. Each sub-unit may handle the real-time data acquisition, processing and/or control of component within the lithographic apparatus. For example, one sub-unit may be dedicated to servo control of the second positioning system PW. Separate sub-units may handle the short-stroke module and the long-stroke module, or different axes. Another sub-unit may be dedicated to the readout of the position sensor IF. Overall control of the lithographic apparatus may be controlled by a central processing unit, communicating with the sub-units, with operators and with other apparatuses involved in the lithographic manufacturing process.

Combinations and/or variations on the above described modes of use or entirely different modes of use may also be employed.

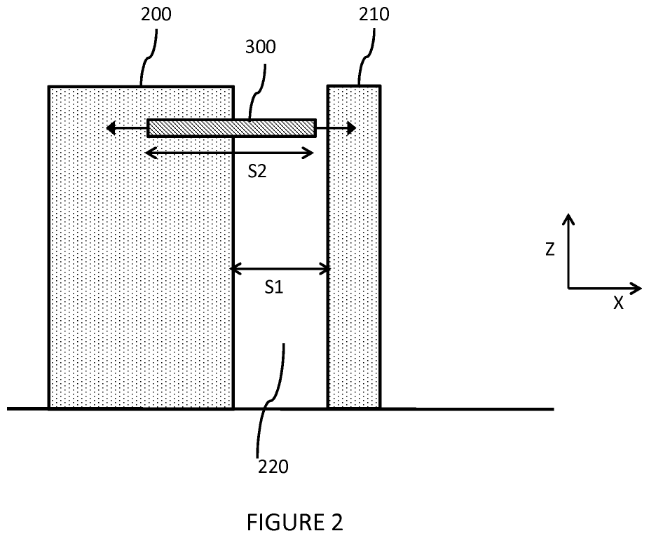

FIG. 2 schematically depicts a cross-section of a part of an environment, for example a cleanroom area in a semiconductor factory, in which a housing 200, for example the housing of a lithographic or semiconductor manufacturing apparatus, is positioned with a space 220, for example the aisle in a semiconductor factory, in between the housing 200 and a wall 210 (or another lithographic or semiconductor manufacturing apparatus). The space 220 has a width S1. The housing 200, for example of a semiconductor manufacturing apparatus such as a lithographic apparatus, comprises an object 300, for example a mask support structure, also named reticle stage, or a wafer stage, with a size, or length, S2, that has to be taken out from the housing to be replaced with an upgraded version. The object 300, or mask support structure, can slide out from the housing 200 in a direction along the X-axis. However, because the width S1 of the space 220 is smaller than the size, or length, S2 of the object 300, it is not possible to slide out the reticle stage 300 entirely in the X-direction, and therefore it is not possible to exchange the reticle stage 300 with an upgraded version in a conventional way. For example, the width S1 can be 1 meter whereas the size S2 of the object 300 can be in the order of 2 meter. Therefore, in general, the aisle width in a semiconductor factory should be large enough to be able to swap objects from any apparatus that is available in the factory. This is however a costly solution in a cleanroom environment.

Therefore there is a need for a method and apparatus that enables exchanging an object that is located in a housing of a semiconductor manufacturing tool or apparatus, in case the available space outside the housing is smaller than a size of the object.

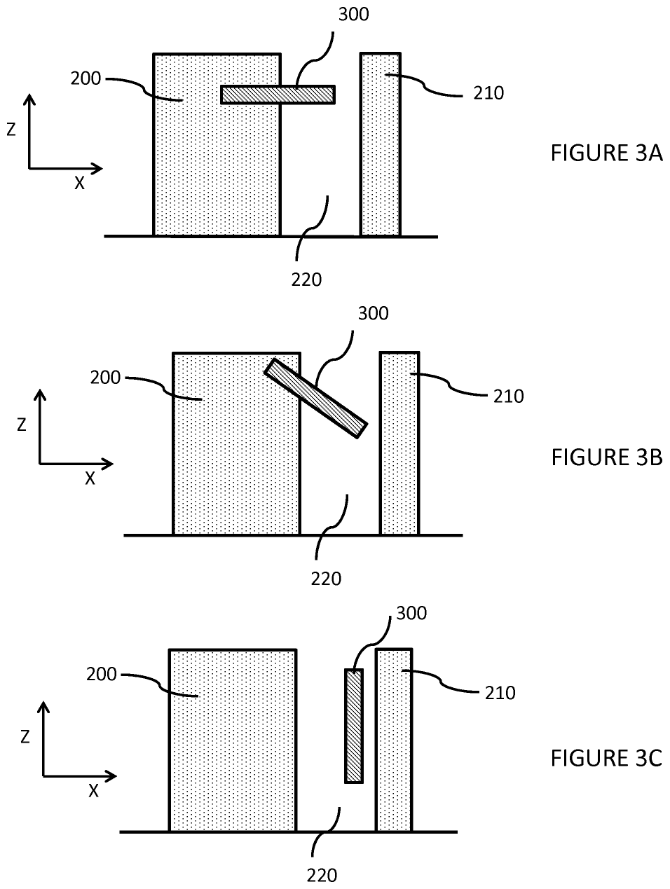

FIGS. 3A-C depict a general representation of a method for moving an object in and/or out from a housing according to an embodiment. The object 300, in this example a mask support structure or reticle stage, is first translated along the X-axis, e.g. horizontally, such that it is partly extending out of a first housing 200, for example the housing of a lithographic apparatus, as is shown in FIG. 3A. This movement can for example be achieved by a guiding mechanism inside the housing. As is shown, the space in between the first housing 200 and a second housing 210 (or a wall) is not large enough to be able to move the reticle stage 300 completely out of the first housing 200 in a horizontal orientation along the X-direction. Therefore, in a next step, as is shown in FIG. 3B, the reticle stage 300 is pivoted or rotated from a first orientation, in this example a generally horizontal orientation extending along the X-axis, towards a second orientation, in this example a generally vertical orientation extending along an axis perpendicular to the X-axis, in this case defined as the Z-axis. Furthermore, this rotation from the first orientation to the second orientation is performed simultaneously with a combined horizontal and vertical translation of a center of mass of the object 300 from a first position to a second position. FIG. 3C shows the situation in which the object 300 is rotated and translated into the second orientation wherein the center of mass is translated into the second position. In this way the object 300 can be transported through the aisle 220 in a generally vertical orientation. In a similar way, but then in reversed order, a new, upgraded version, of the object 300, for example a mask support stage, can be moved into the first housing 200, for example the housing of a lithographic apparatus.

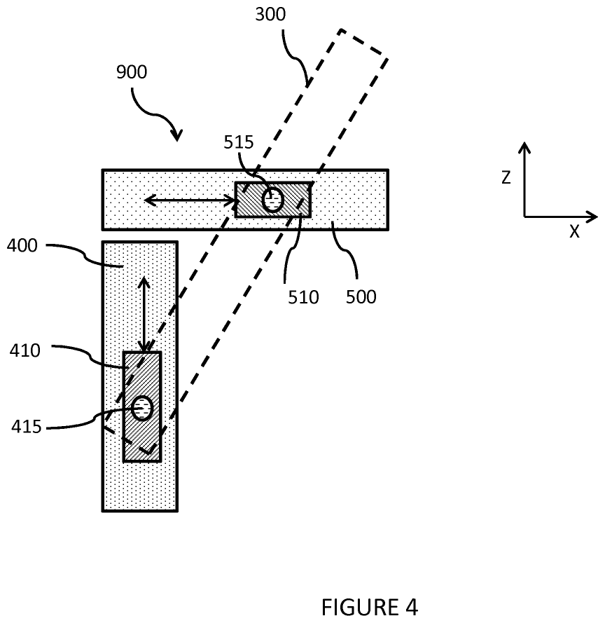

FIG. 4 schematically depicts an apparatus 900 for moving an object 300 in and/or out of a housing according to the method that is depicted schematically in FIGS. 3A-C. The apparatus 900 comprises a first guiding mechanism 400 with a first guide 410 which is in this example movable along a straight line, i.e. linearly, in a first direction, which in this example is a direction along the Z-axis. The apparatus 900 further comprises a second guiding mechanism 500 with a second guide 510 which is in this example movable along a straight line, i.e. linearly, in a second direction, which in this example is a direction along the X-axis. The first direction, i.e. along the Z-axis, is substantially perpendicular to the second direction, i.e. along the X-axis. A first or front part of the object 300 is rotatably connected to the first guide 410 with a first rotatable connection 415, for example a ball joint or a cardan joint. A second part of the object 300 is rotatably connected to the second guide 510 with a second rotatable connection 515, for example a ball joint or a cardan joint. In this respect a rotatable connection is defined as a connection between the guide and the object which allows the object to rotate about an axis with respect to the guide and the object is fixated in such a way that no translation with respect to the guide is possible. The first guide and the second guide are, for example, sliders. The second part is different from the first part of the object 300. The first part and the second part are, for example, near two opposite ends of the object 300. In another example the first part is at one end of the object and the second part is at half or ⅔ of the distance between opposite ends of the object. The distance between the first part and the second part can be selected dependent on the space that is available for moving the object into and/or out of the housing. The first rotatable connection 415 and the second rotatable connection 515 each connect to the first and second guide, respectively, allowing a rotation about a rotation axis which is substantially perpendicular to both the translation direction of the first guide 410 and the translation direction of the second guide 510. The rotation axis of both the first and the second rotatable connections 415, 515 in this example is the Y-axis. It should be noted that the first and second guides do not necessarily have to be moveable along a straight line, but in embodiments it can be for example a curved trajectory. Furthermore, the first and second guides do not necessarily have to be moveable along directions which are mutual perpendicular to each other, as long as the directions, along which the first guide and the second guide are moveable, are different.

By moving, or translating, the first guide 410 upwards, i.e. along the positive Z-axis, the second guide 510 will be forced to move into the direction of the positive X-axis, i.e. in the figure to the right. Because the first and second rotatable connections 415, 515 in this embodiment only allow a rotation about the Y-axis perpendicular to the translation directions of both the first guide 410 and the second guide 510, the object 300 will be rotated from a first, generally vertical, orientation, which in this example is parallel to the Z-axis, to a second, generally horizontal, orientation, which in this example is parallel to the X-axis. The reverse order, in which the object 300 is moved from the second, generally horizontal, orientation, which in this example is parallel to the X-axis, to the first, generally vertical, orientation, which in this example is parallel to the Z-axis, is achieved by moving the first guide 410 downwards, i.e. in the direction of the negative Z-axis, as a result of which the second guide 510 will be forced to move in the negative X-direction, i.e. in the figure to the left. A similar result is achieved by moving the second guide 510 along the X-axis in which case the first guide 410 is forced to move along the Z-axis. Furthermore, due to the movements of the first and the second guides a center of mass or a geometrical center of the object 300 is moved from a first position to a second position both along the Z-axis and along the X-axis. It should be noted that the first.

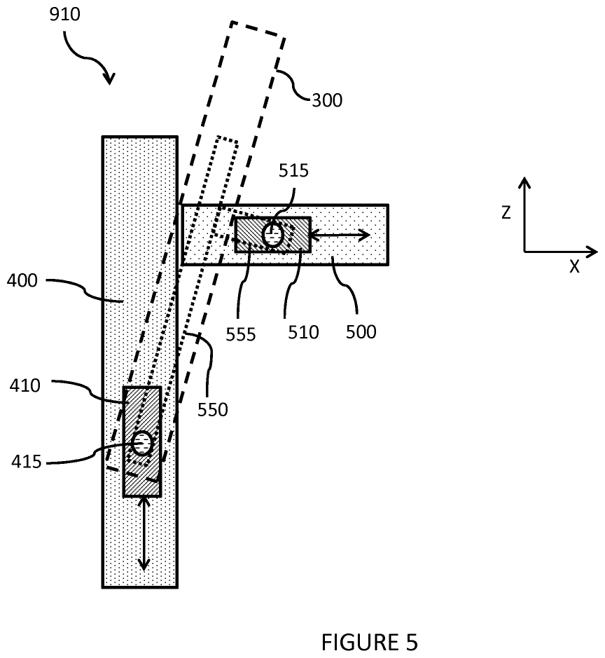

FIG. 5 schematically depicts an apparatus 910 for moving an object 300 in and/or out of a housing according to another embodiment. The difference with the embodiment depicted in FIG. 4 is that in this embodiment the object 300 is fixated to a mechanical interface which comprises a first extension 550 which extends substantially parallel to the main plane of the object and a second extension 555 which extends substantially perpendicular to the main plane of the object 300. Furthermore, in this embodiment a front part of the first extension of the mechanical interface is rotatably connected to the first guide 410 with the first rotatable connection 415, for example a ball joint or a cardan joint. The second extension 555 of the mechanical interface is rotatably connected to the second guide 510 with the second rotatable connection 515, for example a ball joint or a cardan joint. This embodiment enables the first guiding mechanism 400 to extend further along the Z-axis while still allowing for the object to be moved in and/or out of a housing. Above all, this embodiment allows the apparatus to move different objects, for example having a different size, in and/or out of a housing without each object requiring to have a suitable rotatable connection. Furthermore, the mechanical interface provides for a solid and stable interface between the object and the guiding mechanisms providing a stable support of the object (wherein the object can be in different orientations). Another advantage of the mechanical interface is that it provides for flexibility in the position of the first and second rotatable connections thereby allowing the position of the first and second rotatable connections to be selected depending on one or more properties of the objects, for example depending on the size and/or weight of the object. The mechanical interface can also easily be fixated to another tool after the object (including the mechanical interface) has been removed from the housing. For example, the mechanical interface can be fixated to a transport car or to another tool which is arranged to change the orientation of the object (including mechanical interface) for example in case the object has to be stored in another orientation than the orientation of the object after it has been removed from the housing.

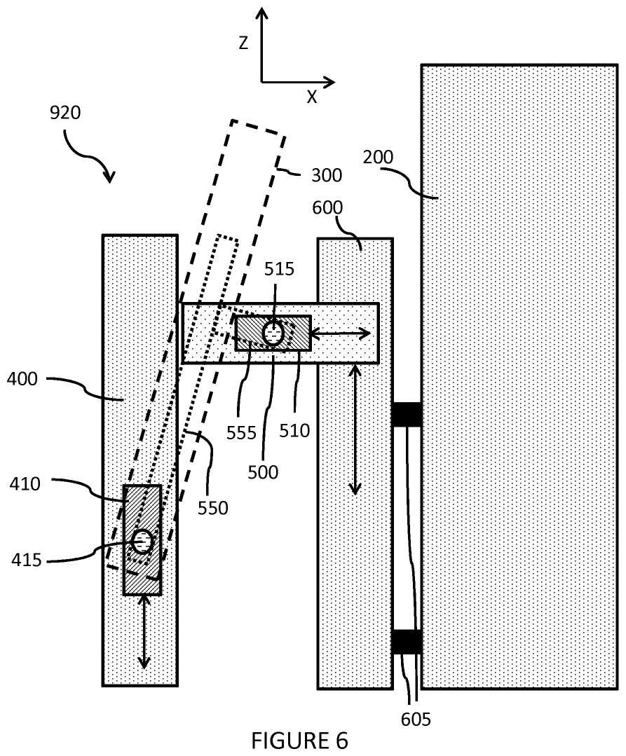

FIG. 6 schematically depicts an apparatus 920 for moving an object 300 in and/or out of a housing according to another embodiment. The difference with the embodiment depicted in FIG. 5 is that in this embodiment the apparatus 920 further comprises a third guiding mechanism 600 which enables the second guiding mechanism 500, including the second guide 510, to move along the Z-axis. In this way the third guiding mechanism 600 allows for the object 300 to be moved in and/or out of a housing 220 (only a part of the housing is shown in FIG. 6) at a selected position along the Z-axis. In an embodiment the third guiding mechanism 600 is fixated to the housing 200, for example to a base frame of a lithographic apparatus, via one or more mechanical connections 605. In another embodiment third guiding mechanism 600 is positioned on a floor. In an embodiment (not shown) the third guiding mechanism 600 comprises a motor which drives the second guiding mechanism 500 to move along the Z-axis, for example by driving a spindle that is connected to the second guiding mechanism 500. Alternatively a hydraulics or pneumatics system is applied to drive the second guiding mechanism 500 to move along the Z-axis. In an embodiment the mechanical interface comprising the first extension 550 and the second extension 555 are not provided and the object is directly rotatably connected to the first and second guides.

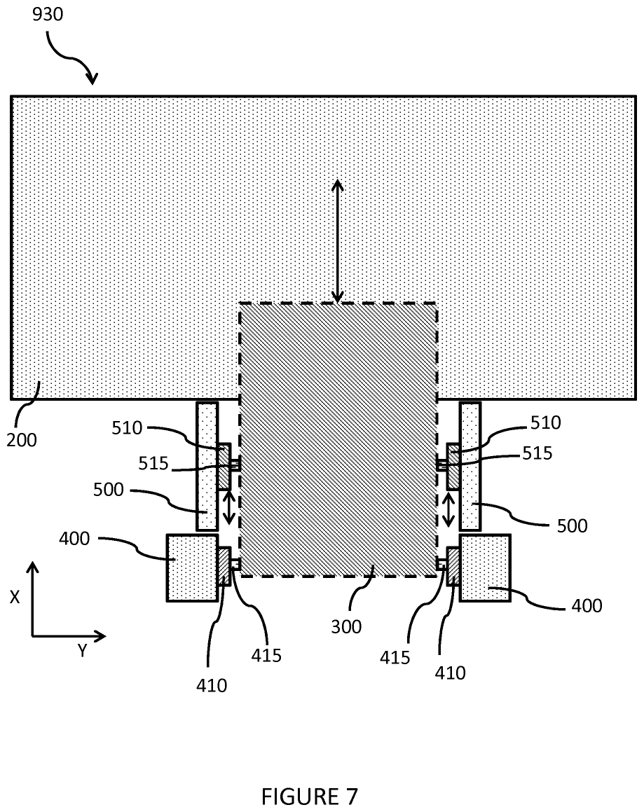

FIG. 7 schematically depicts an apparatus 930 for moving an object 300 in and/or out of a housing according to an embodiment. In this embodiment the schematic view is in the plane of the X- and Y-axis and shows a configuration according to any of the above embodiments in which the first and second guiding mechanisms 400, 500 are provided on two opposite sides of the object 300. This is especially advantageous in case of relatively large and heavy objects. For example the object is a mask support stage of about 2 meter by 2 meter and weighing about 1000 to 1500 kg. In an embodiment the mechanical interface comprising the first extension 550 and the second extension 555 are provided on both opposite sides of the object 330 (not shown in FIG. 7).

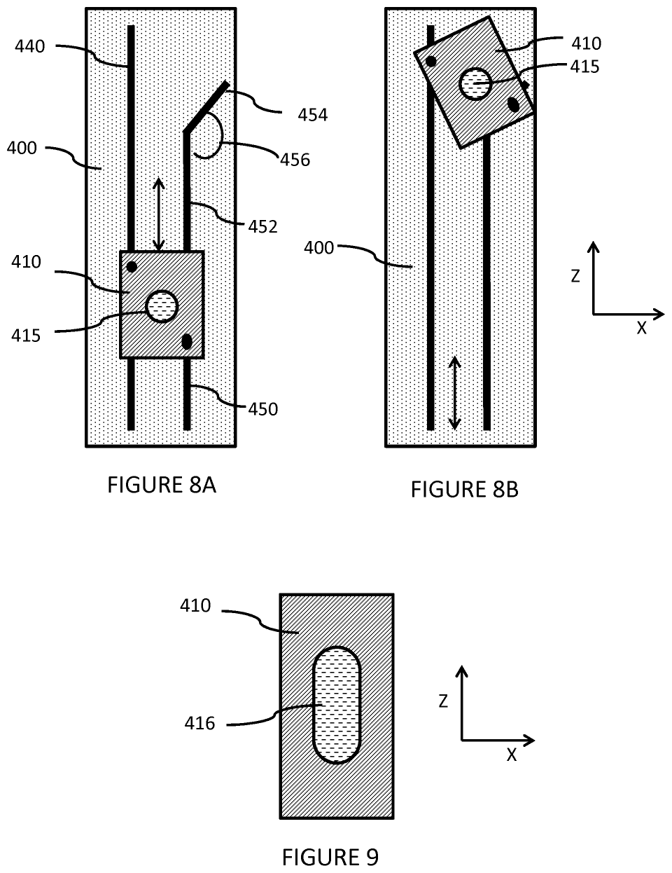

FIGS. 8A and 8B schematically depict an embodiment of the first guiding mechanism 400 with the first guide 410 which provides for an additional, relatively small, translation of the first guide 410 and the rotatable connection 415 in a direction extending along the X-axis. The first guiding mechanism 400 comprises in this embodiment a first guiding rail 440 and a second guiding rail 450. The first guiding rail 440 is generally extending along the Z-axis and comprises for example a trench in the first guiding mechanism 400. The second guiding rail 440 comprises two parts: a first guiding part 452 which is generally extending along the Z-axis which is connected to a second, slanted, guiding part 454 which has an angle 456 with respect to the first guiding part which is larger than 90 degrees and smaller than 180 degrees. The first guiding part 452 and the second guiding part 454 comprise for example a trench in the first guiding mechanism. The first guide 410 comprises a first guide connector 412 and a second guide connector 414. The first guide connector 412 is positioned diagonally in this embodiment opposite to the first guide connector 414, however, generally the first guide connector 412 and the second guide connector 414 are positioned such a movement of rotatable connection 415 in a direction along the X-axis is enabled and possible. The first guide connector 412 cooperates with the first guiding rail 440 and the second guide connector 414 cooperates with the second guiding rail 450, for example a protrusion extending into a trench. The second, slanted, part 454 of the second guiding rail 450 will force the first guide to pivot, or rotate, around the first guide connector 412, as is shown in FIG. 8B. In this way the first rotatable connector 415 will move in a direction along the X-axis thereby moving the object 300 also in a direction along the X-axis. As a result of the additional movement of the object along the X-axis, the object is moved further into and/or out of the housing. It should be noted that the rotatable connector 415 may also be the rotatable connector 416 as depicted in FIG. 7. In another embodiment (not shown) the first guide 410 is pivotly connected to a first guiding device which cooperates with the first guiding rail 440, for example via a rotation axle or joint. The second guiding rail in this embodiment is a trench into which a protrusion of the first guide 410 extends.

FIG. 9 schematically depicts an embodiment of the first guide 410 comprising a slotted socket 416 for receiving a ball shaped stud (not shown). The ball shaped stud is fixated to the object 300 or to the first extension 550 of the mechanical interface. The slotted socket 416 provides for the object to be moved over a relatively small distance along a main axis of the slotted socket, which is in this example along the Z-axis. This allows the object to be suspended in the Z-direction only via the rotatable connection which is closest to the housing. This provides for an improved stability of the apparatus.

In an embodiment the first guiding mechanism 400 is pivotly connected to the housing such that the first guiding mechanism 400 can pivot about the Z-axis and in this way acts as a door. This provides for additional space to position, for example, a transport car in front of the housing at the location of the object, in case there is insufficient space when the first guiding mechanism is an operating position in which the object can be moved into and/or out of the housing. For example, the first guiding mechanism is pivoted such that it is in an open position and close to the housing. Sufficient space is created for a transport car, used for transporting the object, to be moved in front of the housing. Thereafter the first guiding mechanism is pivoted around the Z-axis such that it is in the operating position.

In an embodiment the first guiding mechanism comprises a motor to drive the first guide 410 to move along the Z-axis, for example by driving a spindle that is connected to the first guide 410. The second guide 510 is in this way forced to move along the X-axis. The motor thus indirectly also drives the second guide 510.

In an embodiment the first guide is supported by one or more springs thereby allowing the rotatable connection to move into the Z-direction supporting the object and reducing torsion during the movement of the object. Furthermore this provides for the weight of the object to be distributed more evenly thereby taking into account (and at least partly compensating for) the tolerances in dimensions (e.g. length, width) of the apparatus and/or the object.

In an embodiment the apparatus comprises force sensors arranged to measure a force that is experienced by, for example, the first and/or second guides. In this way a safety check is enabled and any collision can be detected in advance and thus avoided.

In an embodiment the apparatus comprises position sensors, such as interferometers cooperating with encoders, arranged to measure the position of the first and/or second guides.

In an embodiment a console (not shown) is provided for remotely operating the apparatus according to the invention. This is advantageous in case there is no sufficient space available to operate the apparatus and enables to operate the apparatus from a safe distance.

In an embodiment a computer program operates the one or more motors that drive the guides.

Although in the embodiments the object is moved from a horizontal to a vertical orientation, the invention enables moving the object from any orientation to any other orientation, for example to an orientation having an angle of 30 or 45 degrees with respect to the Z-axis.

In the embodiments X-, Y- and Z-axes are defined such that the Z-direction is up and down between a floor and a ceiling of the room in which the housing is positioned, the X-axis is the direction into and/or out of the housing, and the Y-direction is perpendicular to both the Z-axis and the X-axis. It should be understood that the naming of these axes can be different than what is used in the description of the embodiments.

Although specific reference is made to moving a mask support stage in and/or out of the housing of a lithographic apparatus, it should be understood that the invention may be used for moving any object into and/or out of any housing in case there is not enough space available for using the conventional methods.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The descriptions above are intended to be illustrative, not limiting. Thus, it will be apparent to one skilled in the art that modifications may be made to the invention as described without departing from the scope of the claims set out below.

1. An apparatus for moving an object in and/or out of a housing of a lithographic tool, the apparatus comprising:
a first guiding mechanism moveable in a first direction and which is rotatably connectable to a first part of the object, to move the object in and/or out of the housing of the lithographic tool; and
a second guiding mechanism moveable in a second direction and which is rotatably connectable to a second part of the object, to move the object in and/or out of the housing of the lithographic tool,
wherein the second part is different from the first part and the second direction is different from the first direction, and
wherein the rotatable connections define a rotation around an axis which extends in a third direction which is substantially perpendicular to the first direction and the second direction.

2. The apparatus as claimed in claim 1, further comprising a lifting mechanism, fixated to the second guiding mechanism, to provide a movement of the second guiding mechanism in the first direction.

3. The apparatus as claimed in claim 2, wherein the lifting mechanism is, in use, fixated to the housing.

4. The apparatus as claimed in claim 1, further comprising a mechanical interface, in use, fixated to the object, wherein the first guiding mechanism and the second guiding mechanism are rotatably connectable to the object via the mechanical interface.

5. The apparatus as claimed in claim 4, wherein the mechanical interface comprises a first arm and a second arm extending substantially perpendicular to the first arm, wherein the first arm is rotatably connectable to the first guiding mechanism and the second arm is rotatably connectable to the second guiding mechanism.

6. The apparatus as claimed in claim 1, wherein the first guiding mechanism is pivotable around an axis extending in the first direction.

7. The apparatus as claimed in claim 1, wherein the rotatable connections between the first and second guiding mechanisms and the object comprise a ball joint.

8. The apparatus as claimed in claim 1, wherein the rotatable connection between the first guiding mechanism and the object comprises a slotted socket extending in the first direction and a ball stud.

9. The apparatus as claimed in claim 1, comprising:
two first guiding mechanisms, wherein one of the first guiding mechanisms is rotatably connectable to a first part of a first side of the object and the other one of the first guiding mechanisms is rotatably connectable to a first part of a second side of the object which is opposite to the first side, and
two second guiding mechanisms, wherein one of the second guiding mechanisms is rotatably connectable to a second part of the first side of the object and the other one of the second guiding mechanisms is rotatably connectable to a second part of the second side of the object.

10. The apparatus as claimed in claim 1, wherein the first guiding mechanism comprises a first guide which is rotatably connectable to the first part of the object, and wherein the second guiding mechanism comprises a second guide which is rotatably connectable to the second part of the object.

11. The apparatus as claimed in claim 10, wherein the first guiding mechanism comprises a motor configured to drive the first guide in the first direction and configured to provide a movement of the second guide in the second direction.

12. The apparatus as claimed in claim 10, wherein the first guiding mechanism comprises a guiding trench comprising a first linear part connected to a second linear part and wherein the first guide comprises a protrusion which engages in the guiding trench and is pivotably connectable to the first guiding mechanism,
wherein the first and second linear parts have an angle larger than 90 degrees and smaller than 180 degrees with respect to each other.

13. The apparatus as claimed in claim 1, wherein the object comprises a support structure for a mask.

14. A method for moving an object in and/or out of a housing of a lithographic tool, the method comprising:
connecting a first guide to a first part of the object, wherein, when connected, the first guide is rotatably connected to the first part of the object;
connecting a second guide to a second part of the object, which is different from the first part of the object and wherein, when connected, the second guide is rotatably connected to the second part of the object; and
moving the first guide in a first direction thereby moving the second guide in a second direction, which is different from the first direction, and rotating the object around an axis extending in a third direction which is substantially perpendicular to the first direction and the second direction, to move the object in and/or out of the housing of the lithographic tool.

15. The method as claimed in claim 14, further comprising moving the second guide in the first direction before moving the first guide in the first direction.

16. The method as claimed in claim 14, further comprising:
pivoting the first guide around an axis extending in the first direction to an open position;
positioning a transport car in a location close to the housing where the object is located;
pivoting the first guide around the axis extending in the first direction to an operating position; and
after the pivoting to the operating position, connecting the first guide to the first part of the object.

17. An apparatus for moving an object in and/or out of a housing, the apparatus comprising:
a first guiding mechanism moveable in a first straight direction and which is rotatably connectable to a first part of the object, to move the object in and/or out of the housing; and
a second guiding mechanism moveable in a second straight direction and which is rotatably connectable to a second part of the object, to move the object in and/or out of the housing,
wherein the second part is different from the first part and the second straight direction is essentially perpendicular to the first straight direction,
wherein the first and second guiding mechanism are configured to move in the respective straight directions at a same time, and
wherein the rotatable connections define a rotation around an axis which extends in a third direction which is substantially perpendicular to the first direction and the second direction.

18. The apparatus as claimed in claim 17, further comprising a mechanical interface, in use, fixated to the object, wherein the first guiding mechanism and the second guiding mechanism are rotatably connectable to the object via the mechanical interface.

19. The apparatus as claimed in claim 18, wherein the mechanical interface comprises a first arm and a second arm extending substantially perpendicular to the first arm, wherein the first arm is rotatably connectable to the first guiding mechanism and the second arm is rotatably connectable to the second guiding mechanism.

20. The apparatus as claimed in claim 17, wherein the first guiding mechanism is pivotable around an axis extending in the first direction.
